(19) United States
(12) Patent Application Publication
(10) Pub. No.: US 2009/0299660 A1
(43) Pub. Date: Dec. 3, 2009

(54) Method and System to Identify Utility Leaks

(76) Inventor: Dan Winter, Pardessia (IL)

Correspondence Address: THE WEBB LAW FIRM, P.C., 700 KOPPERS BUILDING, 436 SEVENTH AVENUE, PITTSBURGH, PA, 15219, US

(21) Appl. No.: 12/129,240

(22) Filed: May 29, 2008

(51) Int. Cl. G01F 23/00; G01M 3/04; G01R 21/00

(52) U.S. Cl. 702/51; 73/40; 702/61

(57) ABSTRACT

A method for utility monitoring to ascertain unidentified utility consumption, having the steps of: a) providing a utility; b) passing the utility through a primary meter; c) supplying the utility to a plurality of secondary meters after the utility passes through the primary meter; d) measuring a first amount of the utility passing through the primary meter over a first time period; e) measuring the sum of the utility supplied to the plurality of secondary meters over the first time period; and f) determining a difference between the first amount of the utility and the sum of the utility supplied to the plurality of secondary meters over the first time period, wherein the difference is an amount of unidentified utility consumption. Also disclosed is a system for utility monitoring to ascertain unidentified utility consumption. The system has a utility, a primary meter, and a plurality of secondary meters.

### BACKGROUND OF THE INVENTION

1. Field of the Invention

The present invention relates to a method and system for the monitoring and identification of non-revenue utility leaks.

2. Description of Related Art

Presently, many utility providers visually read utility meters to determine utility consumption. However, reading utility meters does not provide an indication as to whether the utility was actually consumed at an endpoint. Many utility losses occur before a utility reaches the utility meter of a residence or business. These utility losses can occur in the form of leaks in the utility line, such as water leaks from a water line, and are indicative of main leaks. In the industry, these utility losses are referred to as “non-revenue leaks” because they occur before the utility reaches the utility of a residence or business. Although some non-revenue leak is acceptable, it is not desirable and results in lost profits for utility providers.

Therefore, it is an object of the present invention to provide a method and system to identify where a non-revenue leak is occurring in a utility system.

### SUMMARY OF THE INVENTION

The present invention provides a method for utility monitoring to ascertain unidentified utility consumption, having the steps of: a) providing a utility; b) passing the utility through a primary meter; c) supplying the utility to a plurality of secondary meters after the utility passes through the primary meter; d) measuring a first amount of the utility passing through the primary meter over a first time period; e) measuring the sum of the utility supplied to the plurality of secondary meters over the first time period; and f) determining a difference between the first amount of the utility and the sum of the utility supplied to the plurality of secondary meters over the first time period, wherein the difference is an amount of unidentified utility consumption. The unidentified utility consumption comprises a leak between the primary meter and one or more of the plurality of secondary meters. The utility is at least one of water, gas or electricity.

The present invention further provides the additional steps of: g) measuring a second amount of the utility passing through the primary meter over a second time period after the first time period; h) measuring the sum of the utility supplied to the plurality of secondary meters over the second time period; i) determining a difference between the second amount of the utility and the sum of the utility supplied to the plurality of secondary meters over the second time period, wherein the difference is an amount of unidentified utility consumption; and j) calculating the difference between step f) and step i) to determine an amount of disparity between the amount of unidentified utility consumption between the first and second time periods.

Further, a plurality of primary meters and a plurality of secondary meters are provided with the present invention wherein a respective plurality of secondary meters is in communication with a respective primary meter. The utility is provided and passed through the plurality of primary meters and the utility is then supplied to the plurality of secondary meters. The first amount of the utility passing through each primary meter is measured over a first time period and the sum of the utility supplied to each respective plurality of secondary meters over the first time period is measured. The difference between the first amount of the utility passed through each primary meter and the sum of the utility supplied to each respective plurality of secondary meters over the first time period is determined to calculate unidentified utility consumption. The first time period is at a time of day of typically low utility consumption, such as, from between the hours of 12:00 a.m. and 6:00 a.m. Further, the primary and secondary meters can be automatic reading utility meters that may be remotely read. The automatic reading utility meters can be on a fixed network. Additionally, the automatic reading utility meters may contain a real time clock to allow for synchronized readings. The automatic reading utility meters can be remotely read by a passing vehicle with a transceiver attached thereto.

With the present invention, the utility is provided to an area that is made up of a plurality of districts. Each district is provided with at least one primary meter and a respective plurality of secondary meters in communication with the at least one primary meter. The utility is provided and passed through the at least one primary meter in each district, and the utility is then supplied to the respective plurality of secondary meters in connection with the at least one primary meter in each district. The first amount of the utility passing through the at least one primary meter is measured over a first time period and the sum of the utility supplied to each respective plurality of secondary meters over the first time period is measured. The difference between the first amount of the utility passed through the at least one primary meter and the sum of the utility supplied to each respective plurality of secondary meters over the first time period is determined to calculate unidentified utility consumption. As such, the amount of unidentified utility consumption can be determined in each district. A master utility meter may be provided and connected to the at least one primary meter of two or more districts. The master utility meter identifies a sum amount of the utility passed through the at least one primary meter of two or more districts. Each district may be further divided into two or more zones, wherein at least one primary meter is provided and connected to each zone. Each zone may also contain a valve to control the supply of utility to the plurality of secondary meters contained therein.

The present invention also provides a system for utility monitoring to ascertain unidentified utility consumption. The system has a utility, a primary meter, and a plurality of secondary meters. With the system, a first amount of a utility passed through the primary meter at a first time period is measured and the sum of the utility supplied to the plurality of secondary meters over the first time period is measured. The difference between the first amount of the utility and the sum of the utility supplied to the plurality of secondary meters over the first time period is determined to identify an amount of unidentified utility consumption. The first time period is at a time of day of typically low utility consumption. Further, the primary and secondary meters are automatic reading utility meters and can be remotely read by a passing vehicle with a transceiver attached thereto. Further, the automatic reading utility meters may contain a real time clock to allow for synchronized readings.

### BRIEF DESCRIPTION OF THE DRAWINGS

FIG. 1 is a schematic view of one embodiment of a method and system to identify utility leaks in accordance with the present invention; and

FIG. 2 is an enlarged partial schematic view of one embodiment of a method and system to identify utility leaks in accordance with the present invention.

### DESCRIPTION OF THE PREFERRED EMBODIMENT

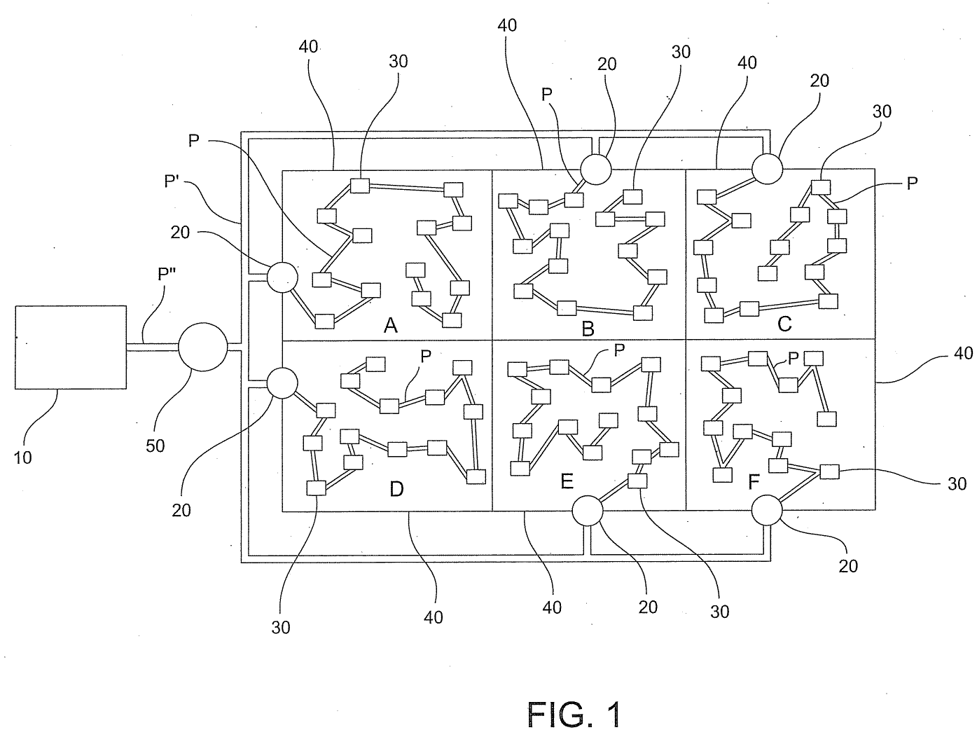

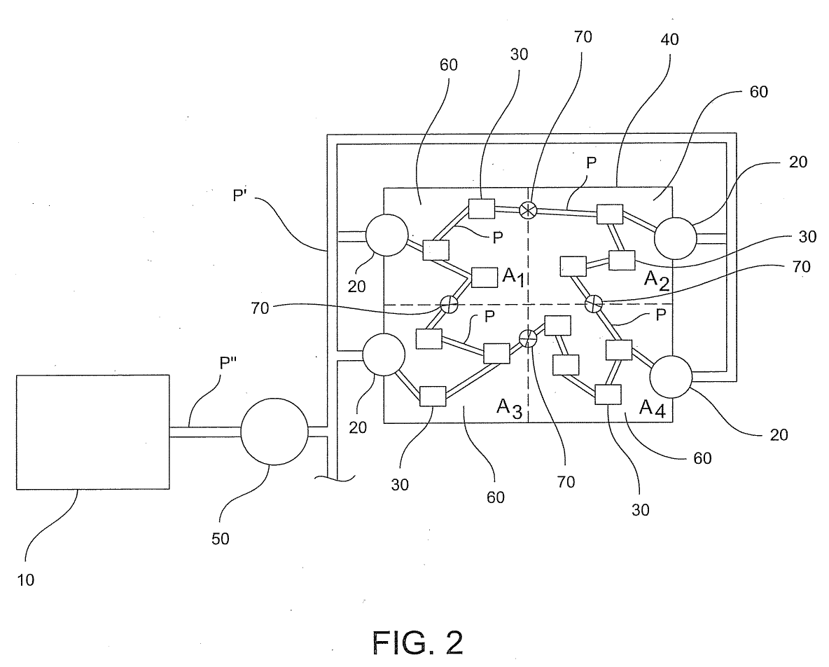

FIGS. 1 and 2 schematically illustrate a method and system to identify utility leaks in accordance with the present invention. FIG. 1 illustrates a utility 10 being provided and passed through at least one primary meter 20 or master utility meter 50 and then supplied to a plurality of secondary meters 30. The utility 10 is shown being provided to a plurality of districts 40. A master utility meter 50 is shown connected to at least one primary meter 20 of two or more districts 40 in order to readily identify the sum of the utility 10 passed through each primary meter 20 of each district 40. FIG. 2 illustrates a further embodiment of the present invention wherein each district 40 is divided into two or more zones 60 to further narrow down an area of unidentified utility consumption. Each zone 60 contains a valve 70 to control the supply of utility 10 to the secondary meters 30 contained therein.

In the case of water or gas, the secondary meters 30 are in fluid communication with the primary meter 20 via pipes P. The secondary meters 30 are arranged in parallel to the primary meters 20. Primary meters 20 are in fluid communication with the master utility meter 50 via pipes P′ and the primary meters 20 are arranged in parallel to the master meter 50. Master meter 50 is in fluid communication with the utility 10 via a pipe P″.

As discussed above, the object of the present invention is to identify where a non-revenue leak is occurring in a utility system. In other words, the present invention allows for the identification of an area of unidentified utility consumption. This task is accomplished as described more fully herein. As shown in FIGS. 1 and 2, a utility 10 is provided and passed through a primary meter 20 that is contained within a district 40. The utility 10 may be one of water, gas or electricity. The utility is supplied to a plurality of secondary meters 30 after the utility 10 passes through the primary meter 20. In one embodiment, the primary meter 20 and secondary meters 30 are automatic reading utility meters, such as the Dialog 3G® meter provided by Master Meter, Inc. The Dialog 3G® meter is described in U.S. Pat. Nos. 7,343,795; 7,126,551; 6,954,178; and 6,819,292, each of which are herein incorporated by reference in their entirety. The primary meter 20 and secondary meters 30 also have transmission capabilities and likewise can be the type of meters as described above, or other types of meters, such as a turbine meter. Further, the primary meter 20 and secondary meters 30 are capable of being remotely read, such as by a passing vehicle with a transceiver attached thereto. Additionally, the primary meter 20 and secondary meters 30 may be on a fixed network system or a non-fixed network system. A fixed network system allows for meter readings to be transmitted to a fixed receiver continuously or at specific times. The fixed receiver then transmits the information to a centralized authority. With a non-fixed network system, meter readings must be remotely read. Additionally, the primary meter 20 and the secondary meters 30 contain a real time clock to allow for synchronized readings.

FIGS. 1 and 2 show a representation of secondary meters 30 positioned along pipes P. It is to be understood that preferably the secondary meters 30 are actively positioned in parallel to one another, not serially. In other words, FIGS. 1 and 2 are just pictorial representations of where the secondary meters 30 are placed relative to pipes P.

Next, a first amount of the utility 10 passing through the primary meter 20 over a first time period is measured. Then, the sum of the utility 10 supplied to the plurality of secondary meters 30 over the first time period is measured. The difference between the first amount of the utility and the sum of the utility supplied to the plurality of secondary meters 30 over the first time period is determined. The difference is an amount of unidentified utility consumption. The unidentified utility consumption is a non-revenue leak between the primary meter 20 and one or more of the plurality of secondary meters 30.

In one embodiment, the first time period is at a time of day of typically low utility 10 consumption, such as from between the hours of 12:00 a.m. and 6:00 a.m. This allows for a decrease in the amount of false determinations of unidentified utility consumption because there are few customers using a given utility 10 between those hours. For instance, if water is the utility 10 being monitored for unidentified utility consumption, fewer residential customers are awake and using water between the hours of 12:00 a.m. and 6:00 a.m., and more preferably between say 1:00 a.m. and 3:00 a.m. Additionally, with a non-fixed network system, less traffic between those hours allows for easier remote readings of the primary meter 20 and the secondary meters 30.

Further, with the present invention, a second amount of the utility 10 passing through the primary meter 20 over a second time period after the first time period is measured. The sum of the utility 10 supplied to the plurality of secondary meters 30 over the second time period is then measured. The difference between the second amount of the utility 10 and the sum of the utility 10 supplied to the plurality of secondary meters 30 over the second time period is determined. The difference is an amount of unidentified utility consumption. The unidentified utility consumption is a non-revenue leak between the primary meter 20 and one or more of the plurality of secondary meters 30. The difference between the first amount of the utility 10 and the sum of the utility 10 supplied to the secondary meters 30 over the first time period and the difference between the second amount of the utility 10 and the sum of the utility 10 supplied to the plurality of secondary meters 30 over the second time period is then calculated to determine an amount of disparity between the amount of unidentified utility consumption between the first and second time periods.

As illustrated in FIGS. 1 and 2, in one embodiment of the present invention, a plurality of primary meters 20 and a plurality of secondary meters 30 are provided wherein a respective plurality of secondary meters 30 is in communication with a respective primary meter 20. The utility 10 is provided and passed through the plurality of primary meters 20 and the utility is then supplied to the plurality of secondary meters 30. The first amount of the utility passing through each primary meter 20 is measured over a first time period and the sum of the utility supplied to each respective plurality of secondary meters 30 over the first time period is measured. The difference between the first amount of the utility 10 passed through each primary meter 20 and the sum of the utility 10 supplied to each respective plurality of secondary meters 30 over the first time period is determined to calculate unidentified utility consumption.

As further illustrated in FIG. 1, in one embodiment of the present invention, the utility 10 is provided to an area that is made up of a plurality of districts 40, represented for illustrative purposes as A, B, C, D, E and F. Each district 40 is provided with at least one primary meter 20 connected thereto and a respective plurality of secondary meters 30 in communication with the at least one primary meter 20. The secondary meters 30 may be attached to residential or commercial properties. The utility 10 is provided and passed through the at least one primary meter 20 in each district 40, and the utility 10 is then supplied to the respective plurality of secondary meters 30 in connection with the at least one primary meter 20 in each district 40. For example, in district 40-A, the utility 10 is provided and passed through primary meter 20-A in district 40-A, and the utility 10 is then supplied to the respective plurality of secondary meters 30-A in connection with primary meter 20-A in district 40-A. A synonymous set-up occurs with districts 40-B through 40-F. The first amount of the utility 10 passing through each primary meter 20 in each district 40 is measured over a first time period and the sum of the utility supplied to each respective plurality of secondary meters 30 in each district 40 over the first time period is measured. The difference between the first amount of the utility 10 passed through the at least one primary meter 20 and the sum of the utility 10 supplied to each respective plurality of secondary meters 30 over the first time period is determined in each district 40 to calculate unidentified utility consumption. As such, the amount of unidentified utility consumption can be determined in each district 40. This allows for a utility provider to more readily identify a district 40 where a utility leak is occurring and go about normal industry practices to specifically identify where the leak is occurring and rectify the situation.

Further, as shown in FIGS. 1 and 2, a master utility meter 50 may be provided and connected to the at least one primary meter 20 of two or more districts 40. The master utility meter 50 readily identifies a sum amount of the utility 10 passed through the at least one primary meter 20 of two or more districts 40. In one embodiment, the master utility meter 50 is an automatic reading utility meter, such as the Dialog 3G® meter provided by Master Meter, Inc. The Dialog 3G® meter is described in U.S. Pat. Nos. 7,343,795; 7,126,551; 6,954,178; and 6,819,292, each of which are herein incorporated by reference in their entirety. The master utility meter 50 also has transmission capabilities. Further, the master utility meter 50 is capable of being remotely read, such as by a passing vehicle with a transceiver attached thereto. Additionally, the master utility meter 50 may be on a fixed network system or a non-fixed network system. A fixed network system allows for meter readings to be transmitted to a fixed receiver continuously or at specific times. The fixed receiver then transmits the information to a centralized authority. With a non-fixed network system, meter readings must be remotely read. Additionally, the master utility meter 50 contains a real time clock to allow for synchronized readings.

Additionally, in a further embodiment of the present invention, and as shown in FIG. 2, each district 40 (such as 40-A) may be further divided into two or more zones 60, represented for illustrative purposes as A₁, A₂, A₃ and A₄. At least one primary meter 20 is provided and connected to each zone 60. Each zone 60 may also contain a valve 70 to control the supply of utility 10 to the plurality of secondary meters 30 contained therein. For example, in zone 60-A₁, the utility 10 is provided and passed through primary meter 20-A₁ in district 40-A, and the utility 10 is then supplied to the respective plurality of secondary meters 30-A₁ in connection with primary meter 20-A₁ in district 40-A. A synonymous set-up occurs with zones 60-A₂-A₄. The first amount of the utility 10 passing through the at least one primary meter 20 is measured over a first time period and the sum of the utility supplied to each respective plurality of secondary meters 30 over the first time period is measured. The difference between the first amount of the utility 10 passed through the at least one primary meter 20 and the sum of the utility 10 supplied to each respective plurality of secondary meters 30 over the first time period is determined to calculate unidentified utility consumption. As such, the amount of unidentified utility consumption can be determined in each zone 60 of district 40-A. This allows for a utility provider to more readily identify a zone 60 where a utility leak is occurring and go about normal industry practices to specifically identify where the leak is occurring and rectify the situation. Further, a valve 70 provided between zones 60 allows for a utility provider to control the flow of utility 10 into or out of a zone 60 to allow isolated monitoring of one or more zones 60 of interest to further pinpoint the area of a utility leak.

In one preferred embodiment of the present invention, in either a fixed network system or non-fixed network system, a reading of an amount of utility 10 supplied to a plurality of secondary meters 30 at a first time point, such as 1:00 a.m., is generated simultaneously by all of the secondary meters 30 in a district 40. The readings are either remotely read by a transceiver (in a non-fixed network system) or automatically transmitted to a centralized authority (in a fixed network system). Then, a reading of an amount of utility 10 supplied to each of the same plurality of secondary meters 30 at a later and second time point, such as 3:00 a.m., is generated simultaneously by all of the secondary meters 30 in a district 40. The readings are either remotely read by a transceiver (in a non-fixed network system) or automatically transmitted to a centralized authority (in a fixed network system). The difference between the sum of readings of the secondary meters 30 at the two time points is compared to the reading of the amount of the utility 10 passed through the respective primary meter 20 of the district 40 between the two time points. Any ascertained difference is indicative of a non-revenue leak. As discussed above, the primary 20 and secondary meters 30 contain a real time clock to allow for synchronized readings. The simultaneous readings of the primary meter 20 and secondary meters 30 assist in determining non-revenue leak of a given utility 10.

In another preferred embodiment of the present invention, a reading of an amount of utility 10 supplied to a plurality of secondary meters 30 at a first time point, such as 1:00 a.m., is generated simultaneously by all of the secondary meters 30 in a district 40. Then, a reading of an amount of utility 10 supplied to each of the same plurality of secondary meters 30 at a later and second time point, such as 3:00 a.m., is generated simultaneously by all of the secondary meters 30 in a district 40. Then, all of the readings are either remotely read by a transceiver (in a non-fixed network system) or automatically transmitted to a centralized authority (in a fixed network system). The difference between the sum of readings of the secondary meters 30 at the two time points is compared to the reading of the amount of the utility 10 passed through the respective primary meter 20 of the district 40 between the two time points. Any ascertained difference is indicative of a non-revenue leak. In some instances an amount of non-revenue leak may be acceptable, say for example, less than ten percent of the volume of fluid through the primary meter 20. However, a non-revenue leak greater than this volume may require attention and be indicative of a water main break. In such an instance an alarm may be issued to the utility. As discussed above, the primary meter 20 and secondary meters 30 contain a real time clock to allow for synchronized readings. The simultaneous readings of the primary meter 20 and secondary meters 30 assist in determining non-revenue leak of a given utility 10.

The present invention also provides a system for utility monitoring to ascertain unidentified utility consumption. The system has a utility 10, a primary meter 20, and a plurality of secondary meters 30. With the system, a first amount of a utility 10 passed through the primary meter 20 at a first time period is measured and the sum of the utility supplied to the plurality of secondary meters 30 over the first time period is measured. The difference between the first amount of the utility 10 and the sum of the utility 10 supplied to the plurality of secondary meters 20 over the first time period is determined to identify an amount of unidentified utility consumption. The first time period is at a time of day of typically low utility consumption. Further, the primary meter 20 and secondary meters 30 are automatic reading utility meters that can be remotely read by a passing vehicle with a transceiver attached thereto. Further, the primary meter 20 and secondary meters 30 contain a real time clock to allow for synchronized readings.

The present invention as described above can be used to determine the leak of any type of utility or fluid, such as water, gas, electricity or petroleum with the use of a respective type of meter.

Having described the presently preferred embodiments of this invention, it is to be understood that it may otherwise be embodied within the scope of the appended claims.

The invention claimed is:

1. A method for utility monitoring to ascertain unidentified utility consumption, comprising the steps of:
a) providing a utility;
b) passing the utility through a primary meter;
c) supplying the utility to a plurality of secondary meters after the utility passes through the primary meter;
d) measuring a first amount of the utility passing through the primary meter over a first time period;
e) measuring the sum of the utility supplied to the plurality of secondary meters over the first time period; and
f) determining a difference between the first amount of the utility and the sum of the utility supplied to the plurality of secondary meters over the first time period, wherein the difference is an amount of unidentified utility consumption.

2. The method of claim 1, wherein the unidentified utility consumption comprises a leak between the primary meter and one or more of the plurality of secondary meters.

3. The method of claim 1, wherein a plurality of primary meters and a plurality of secondary meters are provided with a respective plurality of secondary meters in communication with a respective primary meter, wherein the utility is provided and passed through the plurality of primary meters and the utility is then supplied to the plurality of secondary meters, wherein the first amount of the utility passing through each primary meter is measured over a first time period, and wherein the sum of the utility supplied to each respective plurality of secondary meters over the first time period is measured, wherein the difference between the first amount of the utility passed through each primary meter and the sum of the utility supplied to each respective plurality of secondary meters over the first time period is determined to calculate unidentified utility consumption.

4. The method of claim 3, wherein the utility is provided to an area that is made up of a plurality of districts, each district is provided with at least one primary meter and a respective plurality of secondary meters in communication with the at least one primary meter, wherein the utility is provided and passed through the at least one primary meter in each district, and the utility is then supplied to the respective plurality of secondary meters in connection with the at least one primary meter in each district, wherein the first amount of the utility passing through the at least one primary meter is measured over a first time period, and wherein the sum of the utility supplied to each respective plurality of secondary meters over the first time period is measured, wherein the difference between the first amount of the utility passed through the at least one primary meter and the sum of the utility supplied to each respective plurality of secondary meters over the first time period is determined to calculate unidentified utility consumption, and wherein the amount of unidentified utility consumption can be determined in each district.

5. The method of claim 4, wherein a master utility meter is provided and connected to the at least one primary meter of two or more districts, and wherein the master utility meter identifies a sum amount of the utility passed through the at least one primary meter of two or more districts.

6. The method of claim 1, wherein the first time period is at a time of day of typically low utility consumption.

7. The method of claim 6, wherein said time of day is from between the hours of 12:00 a.m. and 6:00 a.m.

8. The method of claim 1, wherein the primary and secondary meters are automatic reading utility meters.

9. The method of claim 8, wherein the automatic reading utility meters are remotely read.

10. The method of claim 9, wherein the automatic reading utility meters are remotely read by a passing vehicle with a transceiver attached thereto.

11. The method of claim 8, wherein the automatic reading utility meters are on a fixed network.

12. The method of claim 8, wherein the automatic reading utility meters contain a real time clock to allow for synchronized readings.

13. The method of claim 4, wherein each district is further divided into two or more zones and wherein at least one primary meter is provided and connected to each zone.

14. The method of claim 13, wherein each zone contains a valve to control the supply of utility to the plurality of secondary meters contained therein.

15. The method of claim 1, wherein the utility is at least one of water, gas or electricity.

16. The method of claim 1, further comprising the steps of:
g) measuring a second amount of the utility passing through the primary meter over a second time period after the first time period;
h) measuring the sum of the utility supplied to the plurality of secondary meters over the second time period;
i) determining a difference between the second amount of the utility and the sum of the utility supplied to the plurality of secondary meters over the second time period, wherein the difference is an amount of unidentified utility consumption; and
j) calculating the difference between step f) and step i) to determine an amount of disparity between the amount of unidentified utility consumption between the first and second time periods.

17. A system for utility monitoring to ascertain unidentified utility consumption, comprising:
a utility;
a primary meter; and
a plurality of secondary meters,
wherein a first amount of a utility passed through the primary meter at a first time period is measured, and wherein a sum of the utility supplied to the plurality of secondary meters over the first time period is measured, and wherein the difference between the first amount of the utility and the sum of the utility supplied to the plurality of secondary meters over the first time period is determined to identify an amount of unidentified utility consumption.

18. The system of claim 17, wherein the first time period is at a time of day of typically low utility consumption.

19. The system of claim 17, wherein the primary and secondary meters are automatic reading utility meters.

20. The system of claim 19, wherein the automatic reading utility meters are remotely read by a passing vehicle with a transceiver attached thereto.

21. The system of claim 19, wherein the automatic reading utility meters contain a real time clock to allow for synchronized readings.
